(19) United States
(12) Patent Application Publication
(10) Pub. No.: US 2001/0010375 A1
(43) Pub. Date: Aug. 2, 2001

(54) Gallium phosphide semiconductor configuration and production method

(76) Inventors: Gerald Neumann, Regensburg (DE); Gunther Gronninger, Seubersdorf (DE); Peter Heidborn, Zeitlarn (DE); Gerald Schemmel, Zeitlarn (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/728,682

(22) Filed: Dec. 4, 2000

Related U.S. Application Data
(63) Continuation of application No. PCT/DE99/01549, filed on May 26, 1999.

(30) Foreign Application Priority Data
Jun. 2, 1998 (DE) 198 24 566.1

(51) Int. Cl. H01L 33/00; H01L 21/00

(52) U.S. Cl. 257/102; 438/45; 438/46

(57) ABSTRACT

A semiconductor configuration has a substrate made of GaP and an epitaxial layer on the substrate. The expitaxial layer has an n-doped partial layer and a p-doped partial layer. A pn junction is formed at the boundary between the two partial layers. The epitaxial layer contains an impurity which is an element from the 3rd main group and/or from the 5th main group which is not identical to N. The impurity is present at a maximum concentration in the GaP epitaxial layer of between 10¹⁷ and 10¹⁸ cm⁻³.

### CROSS-REFERENCE TO RELATED APPLICATION

This is a continuation of copending International Application PCT/DE99/01549, filed May 26, 1999, which designated the United States.

### BACKGROUND OF THE INVENTION

Field of the Invention

The invention lies in the semiconductor technology field. More specifically, the invention relates to a semiconductor configuration having a substrate made of GaP and a GaP epitaxial layer, which is arranged above the substrate and comprises an n-doped and a p-doped partial layer. A pn junction is formed at a boundary between the two partial layers. An optically active layer region of the GaP epitaxial layer which contains the pn junction is doped with an impurity complex acting as an isoelectric center. The invention further relates to a method for fabricating a semiconductor configuration with the following method steps: a GaP substrate is provided and a GaP epitaxial layer comprising two partial layers having different doping is epitaxially grown, and pn junction is formed in the boundary region between the two partial layers. An optically active layer region of the GaP epitaxial layer which contains the pn junction is doped with an impurity complex that acts as an isoelectric center.

Light-emitting diodes (LED) made of gallium phosphide (GaP) have been known in the art for quite some time. The have developed into one of the most used LEDs.

GaP is an indirect-gap semiconductor material in which non-radiative recombination is predominant. Although LEDs based on a pure GaP semiconductor material are also able to function and have practical areas of application, GaP LEDs, on account of the indirect-gap band structure, are usually doped with impurities in a targeted manner. The effect achieved by incorporating such impurities—also referred to as isoelectric centers—is that a significantly greater portion of the charge carriers recombines accompanied by the emission of light, which enables LEDs of significantly greater luminosity. Diodes designated by GaP:N use impurities made of N as isoelectric centers and emit in the green to yellow spectral region. The electrons injected on the p side of the pn junction are thereby localized by the isoelectric N. The consequently charged N⁻ complex attracts a hole. The electron and the hole form a bound exciton, which then decomposes radiatively.

There are also known GaP LEDs which contain a neutral Zn—O complex as an isoelectric impurity and emit light in the red spectral region. In this case, too, the emission results from the decomposition of an exciton formed on the Zn—O complex.

In addition, LEDs whose optically active epitaxial layer is constructed from a GaAs₁₋ₓPₓ quasiternary III-V mixed crystal are already known. Given a phosphorus content x>0.45, this semiconductor material also has an indirect band transition, so that N impurities are required for radiative recombination. Given x=0.6, an orange-red color is obtained. In order to fabricate LEDs which emit yellow light, the phosphorus content in the mixed crystal can be increased up to 85%. On account of the indirect-gap band structure GaP LEDs are particularly sensitive to contaminants and imperfections in the crystal structure. In order to obtain highly luminous diodes, therefore, it is necessary to choose GaP substrates having the lowest possible dislocation density. A further disadvantage of GaP LEDs is that as the operating time increases, it can be observed that the brightness of the GaP LEDs undergoes a relatively sharp decrease.

Proposals have already been made for having a favorable influence on the decrease in brightness by means of special temperature control profiles during the liquid phase epitaxy, by using the purest possible starting materials, and by providing an electrically active doping. U.S. Pat. No. 4,303,464 describes a Czochralski fabrication method for a GaP crystal in which the crystal is provided with a dopant that is electrically active in GaP. In that case, crystals which have a low defect frequency and good optical properties are obtained.

The publication “Free-exciton radiation from p-i-n diodes of GaP doped with indium and oxygen”, A. Tanaka et al., Applied Physics Letters, volume 28, No. 3 (1976), pages 129-30, discloses a GaP LED which emits intensive green and weak red light. The intrinsic region is produced by the oxygen donors and the intensity of the emitted light is amplified by the In doping.

The book “Halbleiter-Optoelektronik” [Semiconductor Optoelectronics], by Maximilian Bleicher, Dr. Alfred Huthing Verlag GmbH, Heidelberg, 1986, pages 152-61, in particular page 155, describes a GaP:N LED corresponding to the device and the method in the introductory paragraph above.

### SUMMARY OF THE INVENTION

The object of the invention is to provide a semiconductor configuration, based on a GaP substrate, which overcomes the above-noted deficiencies and disadvantages of the prior art devices, and which exhibits good long-term stability behavior and, in particular as an LED, exhibits a small decrease in brightness under current loading. It is a further object of the invention to specify a method for fabricating a semiconductor configuration of that type.

With the above and other objects in view there is provided, in accordance with the invention, a semiconductor configuration, comprising:

a substrate made of gallium phosphide (GaP);

a GaP epitaxial layer on the substrate, the epitaxial layer comprising an n-doped partial layer and a p-doped partial layer, and defining a pn junction in a boundary region between the partial layers;

the GaP epitaxial layer having an optically active layer region including the pn junction and being doped with an impurity complex acting as an isoelectric center; and

an impurity in the GaP epitaxial layer of at least one element selected from the 3rd main group and the 5th main group of elements and not identical to N, and the impurity being present in the GaP epitaxial layer at a maximum impurity concentration of between 10¹⁷ and 10¹⁸ cm⁻³.

The idea underlying the invention is to strain the epitaxially grown crystal lattice in a targeted manner by adding an impurity—not identical to N—from main groups III and/or V. It is assumed that this results in lattice stabilization, the effect of which is that dislocations present on the GaP substrate continue in a manner less pronounced than before as imperfections in the epitaxial layer (i.e. a shielding effect is obtained), and that conversion processes in the grown crystal lattice, which are caused by current loading and are responsible for the decrease in luminous intensity (degradation), are at least partly prevented. In addition to reducing the degradation, this also prolongs the service life of the LEDs.

As a result of the doping of the GaP epitaxial layer with an impurity complex, for example N or Zn—O, which acts as an isoelectric center in the GaP epitaxial layer, LEDs according to the invention can be produced with a high brightness level.

The impurity concentration must not exceed a certain magnitude to ensure that the impurity addition does not, for its part, lead to the production of dislocations or other crystal defects. The maximum concentration value can vary depending on the impurity used, and is always less than 10²⁰ cm⁻³.

In accordance with an added feature of the invention, the impurity concentration is substantially constant over a thickness of the GaP epitaxial layer.

The preferred impurity is In. In principle, all impurity elements of the 3rd and/or 5th main group can be used as the impurity, with the exception of N acting as an isoelectric center (i.e. B, Al, In, Ti, As, Sb, Bi). According to a preferred embodiment of the invention, however, the impurity is In.

In accordance with an additional feature of the invention, a concentration of the impurity complex in the optically active layer region lies between 10¹⁷ and 5·10¹⁸ cm⁻³, preferably between 5·10¹⁷ and 10¹⁸ cm⁻³.

In accordance with a preferred embodiment, the impurity complex is N. In the alternative, Zn—O complexes may act as isolectric centers.

With the above and other objects in view there is provided, in accordance with the invention, a method of fabricating a semiconductor configuration, which comprises the following method steps:

providing a GaP substrate;

epitaxially growing a GaP epitaxial layer comprising two partial layers having mutually different doping and forming a pn junction at a boundary region between the two partial layers;

doping an optically active layer region of the GaP epitaxial layer, including the pn junction, with an impurity complex acting as an isoelectric center; and

introducing an impurity to the GaP epitaxial layer, the impurity being at least one element selected from the 3rd main group and the 5th main group of the periodic table of elements, other than N, at a maximum concentration in the GaP epitaxial layer of about 10¹⁷ to 10¹⁸ cm⁻³.

The preferred implementation of the novel method grows the epitaxy layer with a liquid phase epitaxy (LPE) process.

In accordance with another feature of the invention, indium is added to a gallium solution, prior to the liquid phase epitaxy process, in an amount of at most 1% by weight based on Ga, and preferably at most 0.7% based on Ga.

In accordance with a concomitant feature of the invention, a GaP substrate is provided having a dislocation density of less than 2·10⁵ cm⁻² and, preferably, less than 1·10⁵ cm⁻².

The epitaxy step of the method according to the invention is preferably carried out by means of liquid phase epitaxy (LPE), since LPE enables the growth of a crystal structure having particularly few defects.

Other features which are considered as characteristic for the invention are set forth in the appended claims.

Although the invention is illustrated and described herein as embodied in a GaP semiconductor configuration and method for fabricating it, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic illustration of a sliding apparatus for the liquid phase epitaxy of doped GaP epitaxial layers on a GaP substrate;

FIG. 2a is a partial schematic cross-sectional illustration of the layer structure of an LED according to the invention;

FIG. 2b is a diagram of the dopant, impurity, and impurity concentration profiles in the LED shown in FIG. 2a; and

FIG. 3 is a graph plotting a decrease in brightness of three LEDs as a function of their operating time.

### DESCRIPTION OF THE PREFERRED EMBODIMENTS

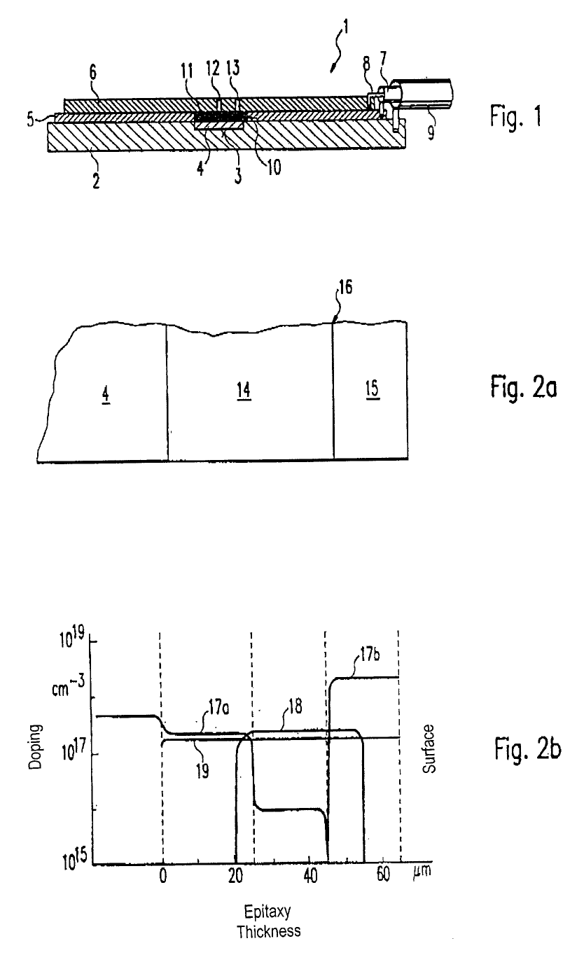

Referring now to the figures of the drawing in detail and first, particularly, to FIG. 1 thereof, there is seen a sliding apparatus 1 which is used in the context of LPE (liquid phase epitaxy) for fabricating an LED according to the invention. The sliding apparatus 1 has a baseplate 2 formed with a depression 3 into which a GaP substrate 4 is inserted. The surface of the GaP substrate 4 is flush with the surface of the baseplate 2. Arranged above the baseplate 2 are a lower and an upper graphite plate 5, 6 which can be displaced both with respect to one another and relative to the baseplate 2. For this purpose, the two graphite plates 5, 6 are coupled to an axial manipulator comprising a sliding tube 7 and a sliding rod 8 guided coaxially in the sliding tube 7. While the sliding tube 7 is coupled to the lower graphite plate 5, the sliding rod 8 is operatively connected to the upper graphite plate 6. The axial manipulator 7, 8 is accommodated in a positionally fixed, i.e., stationary, hollow-cylindrical housing 9, which is fixedly connected to the baseplate 2.

In order to fabricate a GaP:N LED, the GaP substrate is inserted into the depression 3 and a GaP epitaxial material 11 prepared for the epitaxy step is filled into a cutout 10 formed in the lower graphite plate 5. The prepared GaP epitaxial material 11 comprises a pure GaP material to which, by way of example, 0.01% by weight of In, based on Ga, has been added. When this In-enriched GaP epitaxial material 11 is introduced into the cutout 10 in the lower graphite plate 5, the lower graphite plate 5 is oriented relative to the baseplate 2 in such a way that the cutout 10 does not overlap the depression 3, i.e. the GaP epitaxial material 11 is still separated from the GaP substrate 4.

The entire configuration is then brought to a temperature of about 700 to 1000° C. An electrically active dopant is subsequently added to the In-enriched GaP epitaxial material 11 in a suitable manner. In the case of an n-predoped GaP substrate 4, this may involve H₂S (hydrogen sulphide) which is conducted to the epitaxial material 11 via a first opening 12 in the upper graphite plate 6. Afterwards, the lower graphite plate 5 is displaced together with the upper graphite plate 6 on the baseplate 2, so that the GaP epitaxial material 11 passes over and into contact with the GaP substrate 4. The epitaxial layer deposition then takes place on the substrate surface. In this case, the S atoms effect an n-type doping of the epitaxial layer initially growing on the GaP substrate 4.

In order to produce a desired doping profile, the admixture of H₂S can be continuously monitored and controlled.

Furthermore, a second opening 13 is provided in the upper graphite plate 6, through which the nitrogen that is used here for the isoelectric centers is fed by temporary conduction of NH₃ (ammonia). A p-type doping of the growing epitaxial layer can be effected by the addition of Zn vapor, for example, through the first opening 12.

Referring now to FIG. 2a, there is illustrated a layer structure which is produced epitaxially for example by means of the sliding apparatus shown in FIG. 1. FIG. 2b reproduces possible associated concentration profiles of the S and Zn dopants, of the N impurities and of the In impurity used in the present example, plotted against the epitaxial layer thickness.

In accordance with FIG. 2a, the epitaxial layer grown on the n-doped GaP substrate 4 comprises two partial layers 14 and 15. The lower partial layer 14 on the substrate side is n-doped with S and the overlying partial layer 15 has a Zn p-type doping. A pn junction 16 is formed between the two partial layers 14 and 15.

FIG. 2b shows that the n-type doping—provided on the substrate side—of a concentration 17a of, for example, 7·10¹⁷ cm⁻³ in the first epitaxial partial layer 14 falls in a stepped manner toward the pn junction 16 down to about 3·10¹⁵-5·10¹⁶ cm⁻³ (in this case: 1·10¹⁶ cm⁻³). The first partial layer 14 has a layer thickness of about 45 μm in this case.

By contrast, the second partial layer 15 is p-doped with a relatively high concentration in the neighborhood of 2·10¹⁸ cm⁻³. The corresponding profile of the dopant concentration in the second partial layer 15 is identified by the reference symbol 17b. The layer thickness of the second partial layer 15 is about 20 μm in the example illustrated.

The concentration profile of the N impurities for forming the isoelectric recombination centers is represented by the reference symbol 18. The concentration profile has a rectangular profile extending across the pn junction 16. The rectangular profile projects over a length of about 25 μm into the first partial layer 14, and over a length of about 10 μm into the second partial layer 15 of the epitaxial layer. The concentration of the N impurities is 3·10¹⁷ cm⁻³ in this case.

If a higher N concentration is chosen, the maximum of the emission wavelength is shifted on account of the occurrence of an interaction between the N impurities toward longer wavelengths into the yellow spectral region.

The In impurity concentration profile is identified by the reference symbol 19. In the present case, a value of about 2·10¹⁷ cm⁻³ was set, which corresponds to an addition of 0.01% by weight of In, based on Ga, during the epitaxy step. The In concentration may be constant over the thickness of the epitaxial layer 14, 15, as is illustrated by way of example in FIG. 2b. In this case, the lattice stabilization already mentioned is obtained over the entire region of the grown epitaxial layer 14, 15. However, it is also possible to set an In-concentration profile 19 which varies over the layer thickness, and/or to dope only a partial region of the epitaxial layer 14, 15 with In. This may be sufficient and, if appropriate, advantageous, too, because the restructuring processes which are established under current loading in the epitaxial layer 14, 15 and ultimately lead to the degradation of the LED during operation can only occur, or be of significance to the decrease in brightness, in specific regions of the epitaxial layer 14, 15.

Furthermore, for a good quality of the grown GaP epitaxial layer 14, 15, the GaP substrate 4 used should not exceed the smallest possible dislocation density of about 2·10⁵ cm⁻². High-quality GaP substrates 4 having dislocation densities of less than 1·10⁵ cm⁻² should preferably be used.

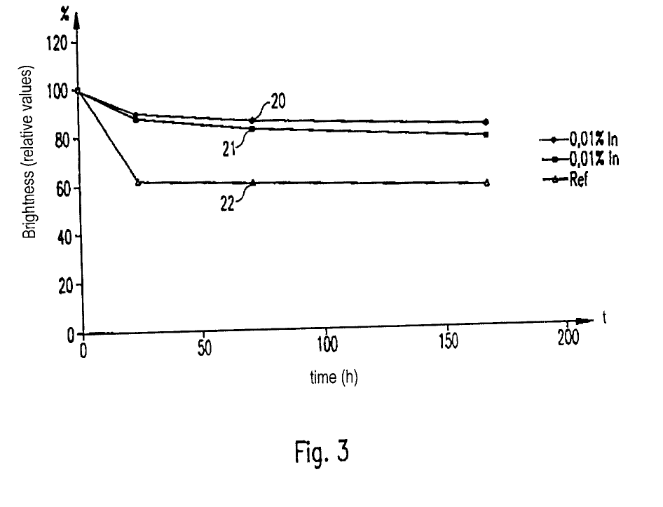

Referring now to FIG. 3, there is shown a diagram in which the measured brightness of three LEDs (measurement points 20, 21, 22) is plotted against the operating time. In order to afford better comparison, the brightnesses of the LEDs are indicated as relative quantities (in percent) based on the respective initial brightnesses (brightnesses when started up for the first time), and therefore have the value 100% for all three LEDs at the instant t=0 h. The filled diamond-shaped 20 and the filled square 21 measurement points reproduce the brightnesses of two GaP:N LEDs according to the invention, whose epitaxial layers 14, 15 were doped, in accordance with FIGS. 2a, 2b, in each case with 0.01% by weight of In based on Ga. The open triangles 22 show measurement points which were recorded for a correspondingly formed conventional reference LED without In admixture. The measurement was made at an operating current of 40 mA and a temperature of 25° C. It becomes clear that both the LEDs according to the invention (measurement points 20, 21) and the reference LED (measurement points 22) exhibit a clearly discernible decrease in brightness as the operating time increases. However, whereas the brightness of the reference LED has already fallen to 60% of its initial brightness after about 25 hours, the LEDs according to the invention still have a brightness of almost 90% of their starting value at this point in time. At the same time, the brightness profiles 20, 21 of the two LEDs according to the invention exhibit good correspondence.

Instead of the n-type doping with S that is described here, Te, for example, may also be used as dopant. Furthermore, instead of N impurities, the above-mentioned Zn—O complexes may also be used as isoelectric centers.

We claim:

1. A semiconductor configuration, comprising:
a GaP substrate;
a GaP epitaxial layer on said substrate, said epitaxial layer comprising an n-doped partial layer and a p-doped partial layer, and defining a pn junction in a boundary region between said partial layers;
said GaP epitaxial layer having an optically active layer region including said pn junction and being doped with an impurity complex acting as an isoelectric center; and
an impurity in said GaP epitaxial layer of at least one element selected from the 3rd main group and the 5th main group of elements and not identical to N, and said impurity being present in said GaP epitaxial layer at a maximum impurity concentration of between 10¹⁷ and 10¹⁸ cm⁻³.

2. The semiconductor configuration according to claim 1, wherein the impurity concentration is substantially constant over a thickness of said GaP epitaxial layer.

3. The semiconductor configuration according to claim 1, wherein said impurity is In.

4. The semiconductor configuration according to claim 1, wherein a concentration of said impurity complex in said optically active layer region lies between 10¹⁷ and 5·10¹⁸ cm⁻³.

5. The semiconductor configuration according to claim 1, wherein a concentration of said impurity complex in said optically active layer region lies between 5·10¹⁷ and 10¹⁸ cm⁻³.

6. The semiconductor configuration according to claim 1, wherein said impurity complex is N.

7. A method of fabricating a semiconductor configuration, which comprises the following method steps:
providing a GaP substrate;
epitaxially growing a GaP epitaxial layer comprising two partial layers having mutually different doping and forming a pn junction at a boundary region between the two partial layers;
doping an optically active layer region of the GaP epitaxial layer, including the pn junction, with an impurity complex acting as an isoelectric center; and
introducing an impurity to the GaP epitaxial layer, the impurity being at least one element selected from the 3rd main group and the 5th main group of the periodic table of elements, other than N, at a maximum concentration in the GaP epitaxial layer of about 10¹⁷ to 10¹⁸ cm⁻³.

8. The method according to claim 7, wherein the growing step is a liquid phase epitaxy process.

9. The method according to claim 8, which comprises, prior to the liquid phase epitaxy process, adding In to a Ga solution used in the liquid phase epitaxy in an amount of at most 1% by weight based on Ga.

10. The method according to claim 8, which comprises, prior to the liquid phase epitaxy process, adding In to a Ga solution used in the liquid phase epitaxy in an amount of at most 0.7% by weight based on Ga.

11. The method according to claim 7, which comprises providing a GaP substrate having a dislocation density of less than 2·10⁵ cm².

12. The method according to claim 7, which comprises providing a GaP substrate having a dislocation density of less than 1·10⁵ cm⁻².
